(19) United States
(12) Patent Application Publication
(10) Pub. No.: US 2017/0018566 A1
(43) Pub. Date: Jan. 19, 2017

(54) SEMICONDUCTOR MEMORY DEVICE

(71) Applicant: Kabushiki Kaisha Toshiba, Minato-ku (JP)

(72) Inventor: Takeshi SONEHARA, Yokkaichi (JP)

(73) Assignee: Kabushiki Kaisha Toshiba, Minato-ku (JP)

(21) Appl. No.: 15/013,166

(22) Filed: Feb. 2, 2016

Related U.S. Application Data
(60) Provisional application No. 62/192,740, filed on Jul. 15, 2015.

(51) Int. Cl. H01L 27/115; H01L 23/528; H01L 23/522

(52) U.S. Cl. CPC H01L 27/11582; H01L 27/11568; H01L 23/5226; H01L 23/5283

(57) ABSTRACT

According to one embodiment, a semiconductor memory device comprises a first stacked body, a column, a second stacked body, a through portion, and a first insulating portion. The first stacked body includes first conductive layers and first insulating layers. The first conductive layers and the first insulating layers are stacked in alternation. The column extends in the first stacked body in a stacking direction of the first conductive layers and the first insulating layers. The second stacked body is separated from the first stacked body on at least one portion of a periphery of the first stacked body. The through portion extends in at least one portion of the second stacked body in the stacking direction. The first insulating portion is provided at the periphery of the first stacked body and at a periphery of the second stacked body.

### CROSS-REFERENCE TO RELATED APPLICATIONS

This application is based upon and claims the benefit of priority from U.S. Provisional Patent Application 62/192,740, filed on Jul. 15, 2015; the entire contents of which are incorporated herein by reference.

### FIELD

Embodiments described herein relate generally to a semiconductor memory device.

### BACKGROUND

A semiconductor memory device is proposed in which memory cells are collected three-dimensionally. This semiconductor memory device is formed by, for example, stacking sacrificial layers and insulating layers in alternation, forming holes through the stacked body, forming memory layers and semiconductor pillars inside the holes, and replacing the sacrificial layers with conductive layers.

Technology is sought that can reduce the possibility of the stacked body collapse in the replacement of the sacrificial layers with the conductive layers.

### BRIEF DESCRIPTION OF THE DRAWINGS

FIG. 1 is a plan view diagram illustrating a portion of the semiconductor memory device 100 pertaining to the first embodiment;

FIG. 2 is a cross-sectional diagram of A-A′ in FIG. 1;

FIG. 3 is a cross-sectional diagram of B-B′ in FIG. 1;

FIG. 4 is a magnified cross-sectional diagram of a portion of the semiconductor memory device 100 pertaining to the first embodiment;

FIGS. 5 and 6 are magnified cross-sectional diagrams of other portions of the semiconductor memory device 100 pertaining to the first embodiment;

FIGS. 7A and 7B are magnified plan views of a portion of the semiconductor memory device 100 pertaining to the first embodiment;

FIGS. 8A and 8B are magnified plan views of another portion of the semiconductor memory device 100 pertaining to the first embodiment;

FIGS. 9A and 9B to 16A and 16B are process diagrams illustrating a manufacturing process for the semiconductor memory device 100 pertaining to the first embodiment;

FIG. 17 is a plan view diagram illustrating a portion of the semiconductor memory device 200 pertaining to the second embodiment;

FIG. 18 is a magnified plan view diagram of a portion of the semiconductor memory device 200 pertaining to the second embodiment;

FIG. 19 is a cross-sectional diagram of A-A′ in FIG. 17;

FIG. 20 is a cross-sectional diagram of B-B′ in FIG. 17;

FIG. 21 is a plan view diagram illustrating a portion of the semiconductor memory device 200 pertaining to the third embodiment; and

FIG. 22 is a cross-sectional diagram of B-B′ in FIG. 21;

### DETAILED DESCRIPTION

According to one embodiment, a semiconductor memory device comprises a first stacked body, a column, a second stacked body, a through portion, and a first insulating portion. The first stacked body includes a plurality of first conductive layers and a plurality of first insulating layers. The first conductive layers and the first insulating layers are stacked in alternation. The column extends in the first stacked body in a stacking direction of the first conductive layers and the first insulating layers. The column includes a semiconductor pillar and a charge storage layer. The semiconductor pillar extends in the stacking direction. The charge storage layer is provided between the semiconductor pillar and the first stacked body. The second stacked body is separated from the first stacked body on at least one portion of a periphery of the first stacked body. The second stacked body includes a plurality of second conductive layers and a plurality of second insulating layers. The second conductive layers and the second insulating layers are stacked in alternation. The through portion extends in at least one portion of the second stacked body in the stacking direction. The first insulating portion is provided at the periphery of the first stacked body and at a periphery of the second stacked body.

Embodiments of the invention are described below, with reference to the accompanying drawings.

The drawings are schematic and conceptual. The relationship between thickness and width of the components, the size ratios among parts, and the like are not necessarily guaranteed to match reality. In addition, dimensions and ratios in the drawings may be represented as different, despite illustrating identical parts.

Also, in the specification and drawings, identical reference signs are used for components identical to those previously described, and detailed explanations thereof are omitted for convenience.

The explanations of each embodiment use an XYZ orthogonal coordinate system. Two orthogonal directions parallel to a main surface of a semiconductor layer S are defined as the X-direction and the Y-direction, while a direction orthogonal to both the X-direction and the Y-direction is defined as the Z-direction.

### First Embodiment

A semiconductor memory device 100 is, for example, a nonvolatile semiconductor memory device capable of electrical data erasing and writing, and able to retain memory content despite being cut off from a power supply.

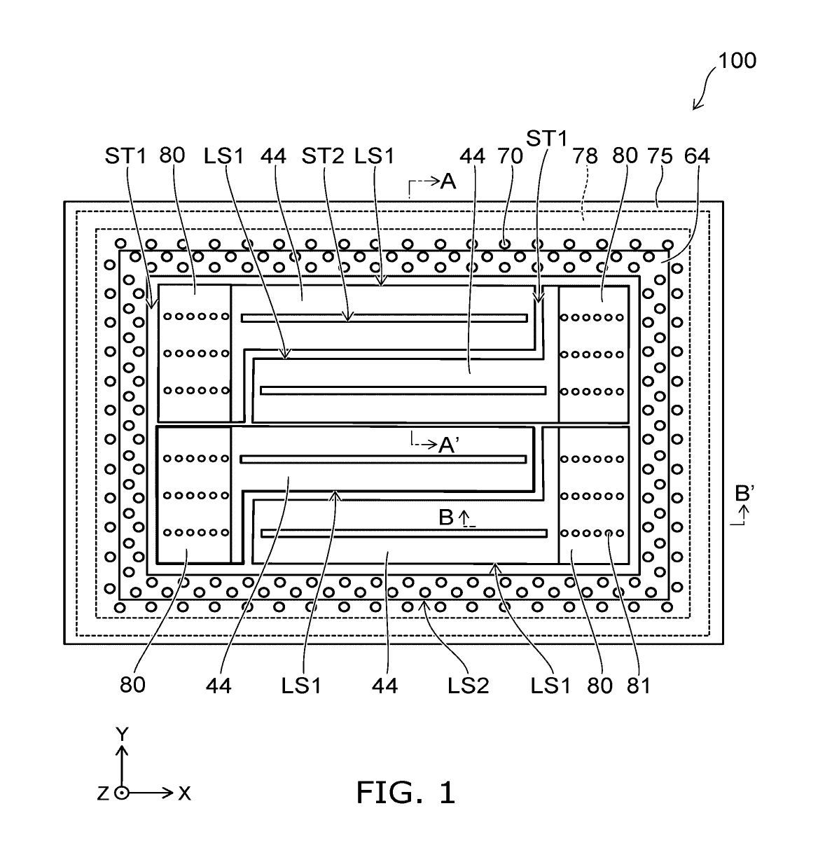

FIG. 1 is a plan view diagram illustrating a portion of the semiconductor memory device 100 pertaining to the first embodiment.

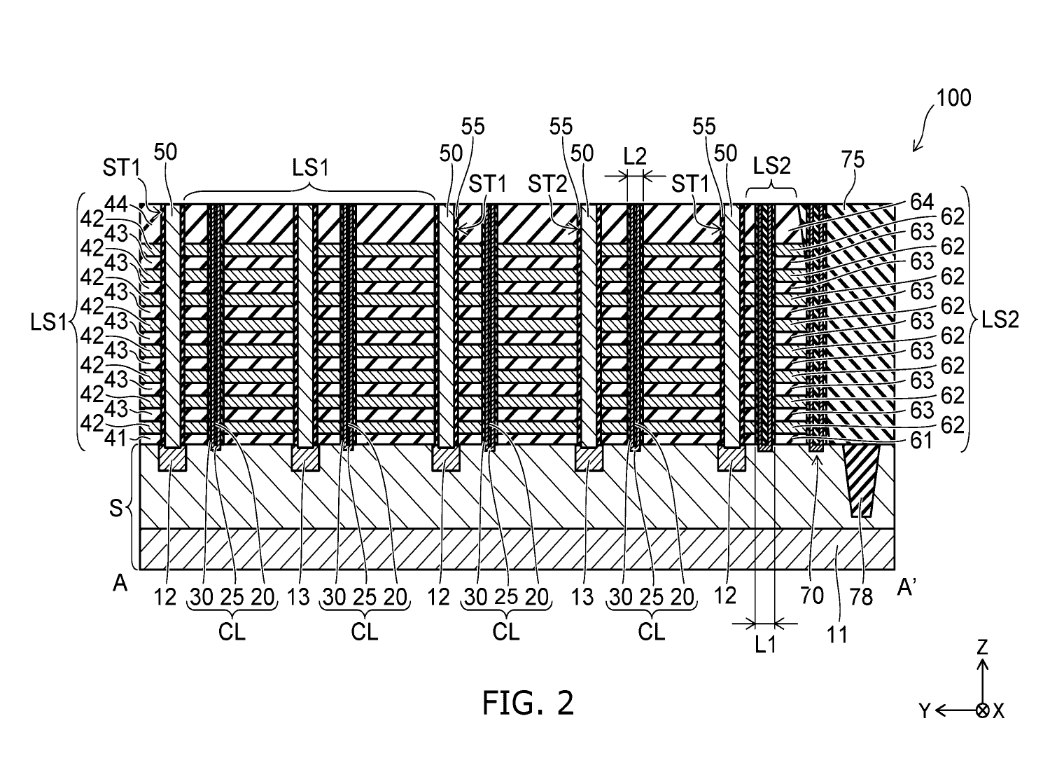

FIG. 2 is a cross-sectional diagram of A-A′ in FIG. 1.

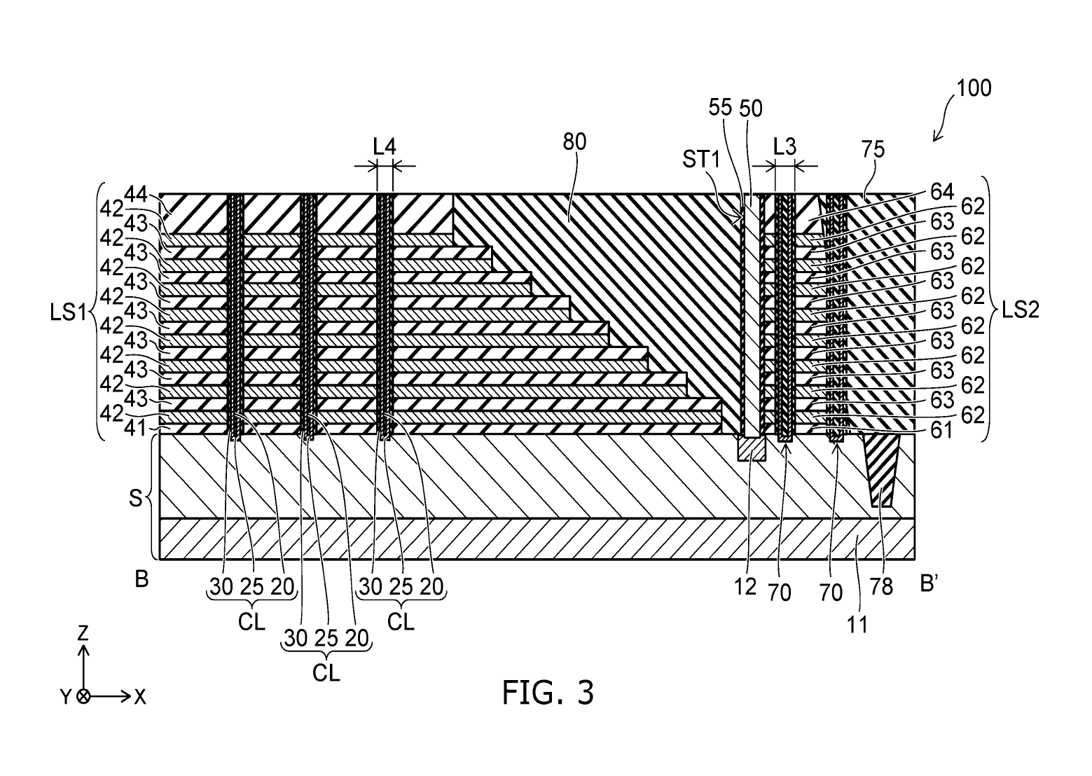

FIG. 3 is a cross-sectional diagram of B-B′ in FIG. 1.

In FIG. 1, the detailed structure of a plurality of slits ST1 and slits ST2, as well as of respective columns CL formed in each of a plurality of first stacked bodies LS1, are omitted for ease of understanding. In addition, FIG. 1 indicates a position at which an insulating portion 78 is provided in dashed lines, as seen in a plan view. Here, the term plan view signifies the appearance of the semiconductor memory device 100 as viewed from the Z-direction.

As illustrated in FIG. 1, the semiconductor memory device 100 includes the first stacked bodies LS1, a second stacked body LS2, a plurality of through portions 70, an insulating portion 75, the insulating portion 78, and an insulating portion 80.

The first stacked body LS1 is provided in plurality in the X-direction and in the Y-direction. The number of the first stacked bodies LS1 illustrated in FIG. 1 is intended as an example. The semiconductor memory device 100 may include the first stacked bodies LS1 in a greater number than the number of the first stacked bodies LS1 illustrated in FIG. 1.

The second stacked body LS2 is provided at the periphery of the first stacked bodies LS1. That is, the first stacked bodies LS1 are surrounded by the second stacked body LS2.

The slits ST1 are provided between the first stacked bodies LS1, and between the first stacked bodies LS1 and the second stacked body LS2. That is, the first stacked bodies LS1 and the second stacked body LS2 are separated from each other by the slits ST1. As illustrated in FIG. 1, the slits ST2 are each provided at positions surrounded by the first stacked bodies LS1, as seen in a plan view. However, the slits ST2 need not necessarily be provided.

The insulating portion 75 is provided at the periphery of the second stacked body LS2. That is, the second stacked body LS2 and the first stacked bodies LS1 are surrounded by the insulating portion 75.

The through portions 70 are provided in the second stacked body LS2. The through portions 70 are provided at the periphery of the first stacked bodies LS1. That is, the first stacked bodies LS1 are surrounded by the through portions 70. The through portions 70 may be partially provided in the insulating portion 75.

The first stacked bodies LS1 are partially covered by the insulating portion 80. The insulating portion 80 is provided between at least a portion of the first stacked bodies LS1 and a portion of the second stacked body LS2, in terms of the X-direction. A plurality of contacts 81 are provided in the insulating portion 80. Each of the contacts 81 is respectively connected to one of a plurality of conductive layers 42, as described later.

As seen in a plan view, the insulating portion 78 is provided at the periphery of the second stacked body LS2 and the first stacked bodies LS1. The insulating portion 78 may overlap with the second stacked body LS2 as seen in a plan view. The insulating portion 78 serves, for example, as shallow trench isolation (hereinafter, STI).

As illustrated in FIG. 2, the semiconductor memory device 100 is, for example, formed on a semiconductor layer S. The semiconductor layer S is, for example, an n-type semiconductor substrate. A p-type semiconductor region 11 is provided on the surface of the semiconductor layer S. A plurality of n-type semiconductor regions 12 and a plurality of p-type semiconductor regions 13 are provided on the surface of the p-type semiconductor region 11. The n-type semiconductor regions 12 are respectively provided at a distance from the p-type semiconductor regions 13.

The first stacked bodies LS1 and the second stacked body LS2 are provided on the semiconductor layer S.

Each of the first stacked bodies LS1 includes an insulating layer 41, the conductive layers 42, a plurality of insulating layers 43, and an insulating layer 44. The conductive layers 42 and the insulating layers 43 are stacked in alternation. The conductive layers 42 each have sufficient conductivity to function as respective gate electrodes of memory cells.

The second stacked body LS2 includes an insulating layer 61, a plurality of conductive layers 62, a plurality of insulating layers 63, and an insulating layer 64. The conductive layers 62 and the insulating layers 63 are stacked in alternation. A material of the insulating layer 61 and a material of the insulating layer 41 may be identical. A material of the conductive layers 62 and a material of the conductive layers 42 may be identical. A material of the insulating layers 63 and a material of the insulating layers 43 may be identical. A material of the insulating layer 64 and a material of the insulating layer 44 may be identical.

The columns CL are provided in the X-direction and in the Y-direction. Each of the columns CL extends in the first stacked bodies LS1 in a stacking direction of the conductive layers 42 and the insulating layers 43 (i.e., the Z-direction).

The columns CL each include, for example, a memory layer 30, a semiconductor pillar 20, and an insulating portion 25. The memory layer 30 is provided at least partially between the semiconductor pillar 20 and the first stacked bodies LS1. The insulating portion 25 may be provided on an inner side of the semiconductor pillar 20. A plurality of bit lines, which are not illustrated in the drawings, are provided on the columns CL. Each of the columns CL is connected to a corresponding one of the bit lines.

A charge trap memory cell is configured, for example, from the memory layer 30 and the conductive layers 42. Each memory cell formed by the memory layer 30 and the respective conductive layers 42 is connected in series through the semiconductor pillar 20. This configures a memory string MS.

A plurality of conductive portions 50 and a plurality of insulating portions 55 are formed in the slits ST1 and in the slits ST2. The conductive portions 50 and the insulating portions 55 extend in the first stacked bodies LS1. The insulating portions 55 are provided between the conductive portions 50 and the first stacked bodies LS1, and between the conductive portions 50 and the second stacked body LS2.

The conductive portions 50 formed within the slits ST1 are, for example, connected to the n-type semiconductor regions 12. The conductive portions 50 formed within the slits ST2 are, for example, connected to the p-type semiconductor regions 13.

A contact surface between the second stacked body LS2 and the insulating portion 75 is tapered, for example. That is, a distance from one end to another of the second stacked body LS2 in the X-direction, and a distance from one end to another of the second stacked body LS2 in the Y-direction, each decrease along the Z-direction.

A subset of the through portions 70 extend in the second stacked body LS2. Another subset of the through portions 70 extend in the second stacked body LS2 and through the insulating portion 75. Alternatively, all of the through portions 70 extend in the second stacked body LS2.

The diameter of each through portion 70 is, for example, greater than the diameter of the columns CL. That is, as illustrated in FIG. 2, a length L1 in the Y-direction of the through portions 70 is longer than a length L2 in the Y-direction of the columns CL. As illustrated in FIG. 3, a length L3 in the X-direction of the through portions 70 is longer than a length L4 in the X-direction of the columns CL. However, the diameter of the through portions 70 may also be equal to the diameter of the columns CL.

The insulating portion 78 is provided in the semiconductor layer S, which is below the insulating portion 75. The insulating portion 78 may also be provided below the second stacked body LS2. That is, the second stacked body LS2 and the insulating portion 78 may be aligned in the Z-direction.

As illustrated in FIG. 3, the respective conductive layers 42 vary in length in the X-direction. As an example the length in the X-direction grows longer with increasing proximity of the conductive layers 42 to the semiconductor layer S. Each of the conductive layers 42 is connected to a different one of a plurality of word lines, which are not illustrated in the drawings, through a respective one of the contacts 81.

The insulating portion 80 is provided between at least a portion of the first stacked bodies LS1 and at least a portion of the second stacked body LS2, in terms of the X-direction.

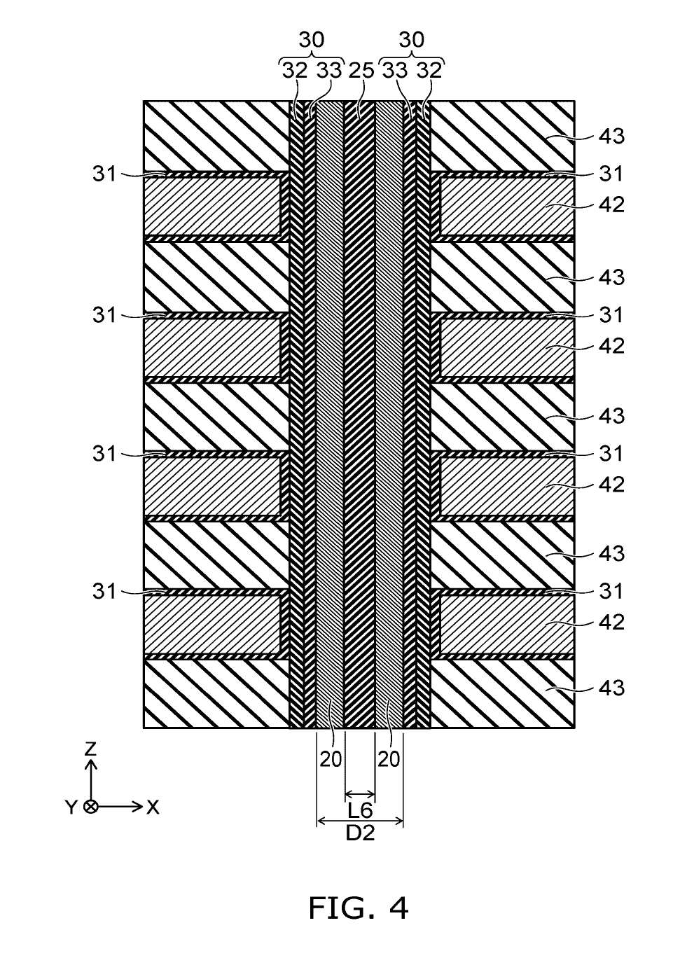

FIG. 4 is a magnified cross-sectional diagram of a portion of the semiconductor memory device 100 pertaining to the first embodiment.

As illustrated in FIG. 4, the memory layer 30 includes a charge storage layer 32 and a tunnel layer 33. The tunnel layer 33 is provided between the semiconductor pillar 20 and the first stacked bodies LS1. The charge storage layer 32 is provided between the tunnel layer 33 and the first stacked bodies LS1.

A plurality of block layers 31 are provided between the charge storage layer 32 and each of the conductive layers 42. The block layer 31 is, for example, provided in plurality in terms of the Z-direction. Each of the block layers 31 is, for example, provided between the conductive layers 42 and the insulating layers 43.

The semiconductor pillar 20 functions as a region where a channel is formed while the semiconductor memory device 100 is operating. The conductive layers 42 function as control gates for the memory cells. The charge storage film 32 functions as a data memory layer that stores electric charges injected from the semiconductor pillar 20. That is, the memory cells are formed at intersecting portions of the semiconductor pillar 20 and the conductive layers 42, having a structure where a channel periphery is surrounded by the control gates.

The block layers 31 are insulating layers. The electric charges stored by the charge storage layer 32 are thereby prevented from dispersing to the conductive layers 42. The block layer 31 is a silicon oxide layer, for example.

The charge storage layer 32 includes a multitude of trap sites that capture electric charges. The charge storage layer 32 is, for example, a silicon nitride layer.

The tunnel layer 33 is an insulating layer. The tunnel layer 33 functions as a charge barrier upon injection of the electric charges into the charge storage layer 32 from the semiconductor pillar 20, and upon dispersion of the electric charges stored in the charge storage layer 32 to the semiconductor pillar 20. The tunnel layer 33 is a silicon oxide layer, for example.

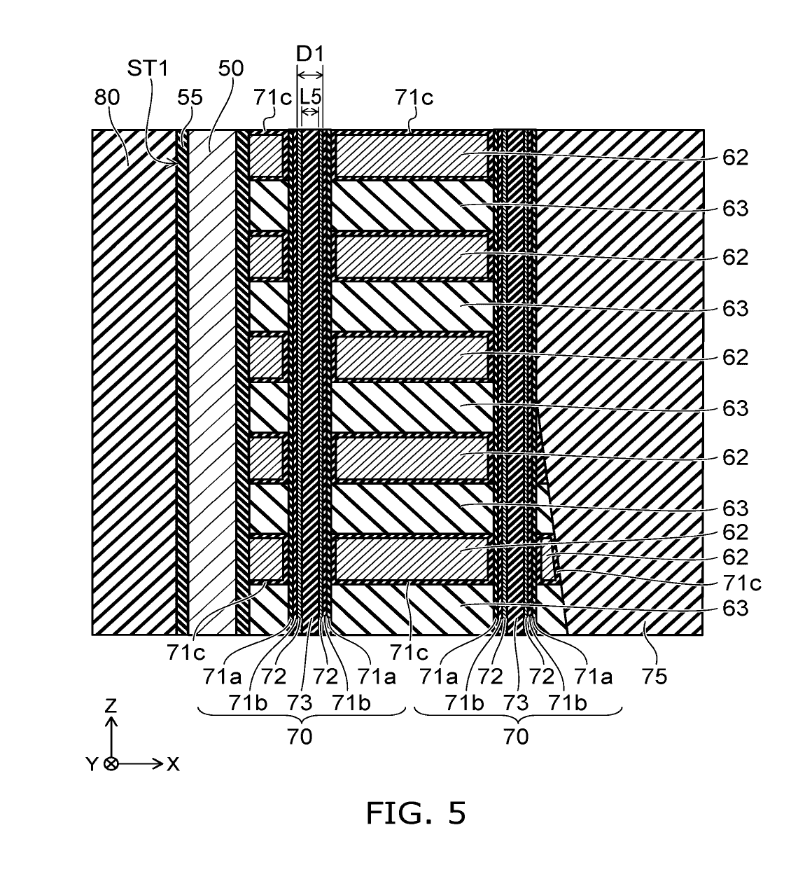

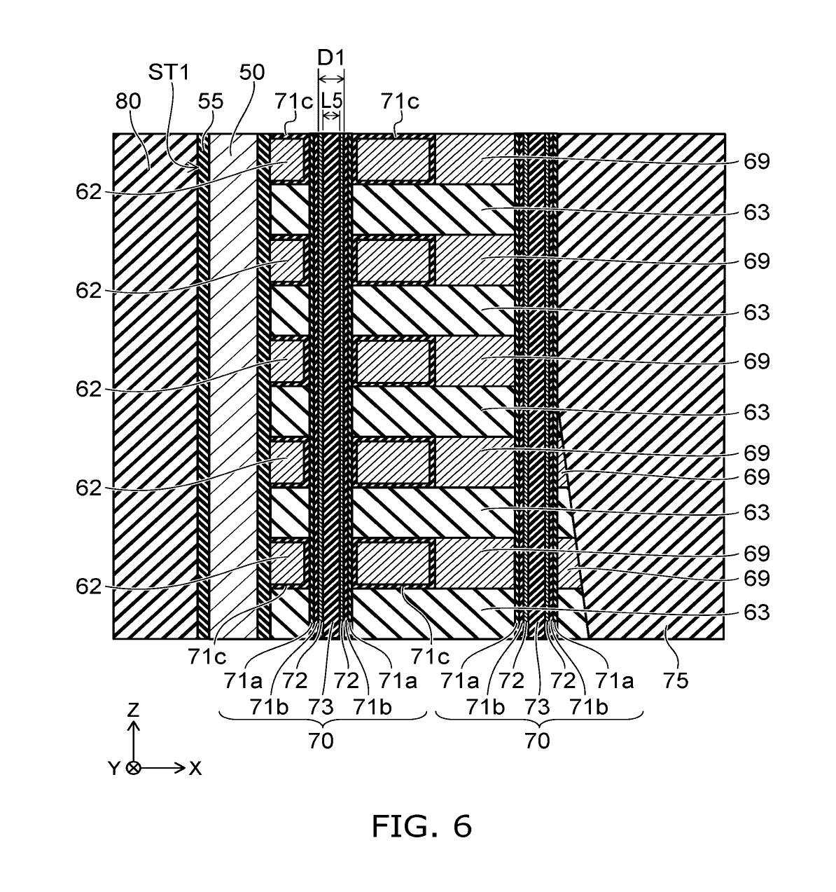

FIGS. 5 and 6 are magnified cross-sectional diagrams of other portions of the semiconductor memory device 100 pertaining to the first embodiment.

For example, as illustrated in FIG. 5, the through portions 70 each include an insulating layer 71a, an insulating layer 71b, a semiconductor portion 72, and an insulating portion 73.

The materials for each of the layers and portions are given as examples. A material of the insulating layer 71a and a material of the charge storage layer 32 are identical. A material of the insulating layer 71b and a material of the tunnel layer 33 are identical. A material of the semiconductor portion 72 and a material of the semiconductor pillar 20 are identical. A material of the insulating portion 73 and a material of the insulating portion 25 are identical.

In this situation, a length L5 in the X-direction of the insulating portion 73 included in each of the through portions 70 illustrated in FIGS. 5 and 6 is, for example, longer than a length L6 in the X-direction of the insulating portion 25 illustrated in FIG. 4. Similarly, a length in the Y-direction of the insulating portion 73 is, for example, longer than a length in the Y-direction of the insulating portion 25.

Furthermore, in such a situation, a distance D1 from one end to another of the semiconductor portion 72 in the X-direction illustrated in FIGS. 5 and 6 is, for example, greater than a distance D2 from one end to another of the semiconductor pillar 20 in the X-direction illustrated in FIG. 4. Similarly, a distance from one end to another of the semiconductor portion 72 in the Y-direction is, for example, longer than a distance from one end to another of the semiconductor pillar 20 in the Y-direction.

In addition, the through portions 70 may be formed only from a conducting material, and may also be formed only from an insulating material. In addition, the through portions 70 may be formed only from a semiconductor material.

In the second stacked body LS2, for example, as illustrated in FIGS. 5 and 6, a plurality of insulating layers 71c are provided between the conductive layers 62 and the insulating layers 63. The insulating layers 71c may be further provided between the conductive layer 62 and the through portions 70. The insulating layers 71c may be further provided between the conductive layer 62 and the insulating portion 75. A material of the insulating layers 71c is, for example, identical to a material of the block layer 31.

The second stacked body LS2 includes a plurality of layers 69, as illustrated in FIG. 6. In the example illustrated in FIG. 6, the conductive layers 62, the layers 69, and the insulating layers 71c are provided between the insulating layers 63. The layers 69 are provided between the conductive layers 62 and the insulating portion 75. The insulating layers 71c are provided between the conductive layers 62 and the layers 69. The layers 69 include an insulating material, for example. The layers 69 may include a semiconductor material, and may also include a conductive material. A material of the layers 69 is, for example, identical to a material of a sacrificial layer 45, which is described later.

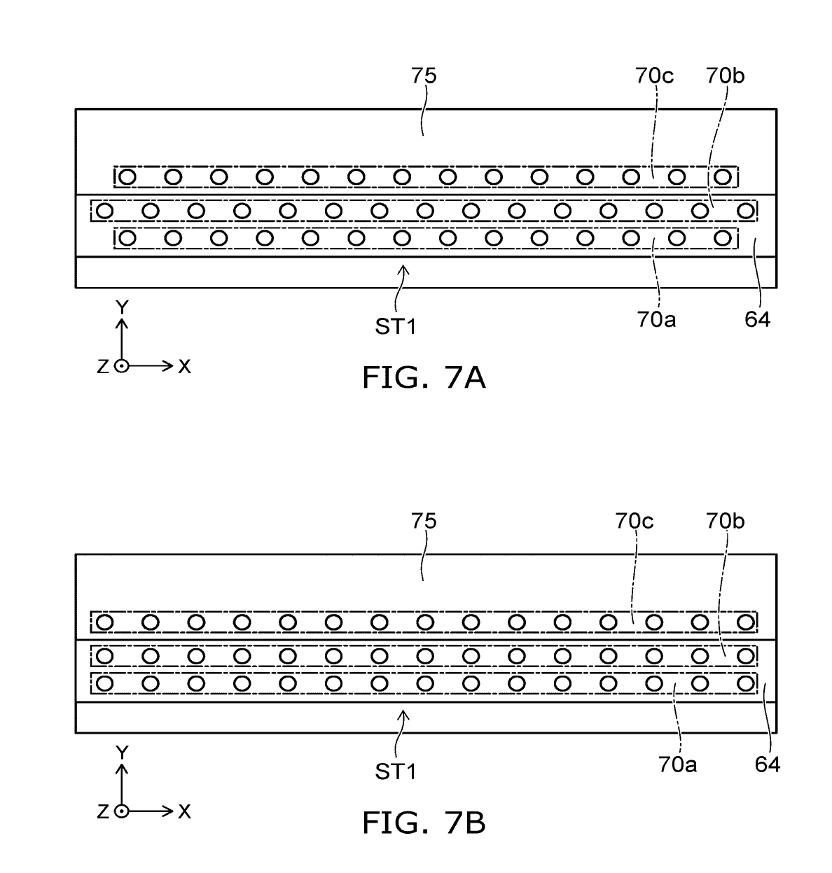

FIGS. 7A and 7B are magnified plan views of a portion of the semiconductor memory device 100 pertaining to the first embodiment.

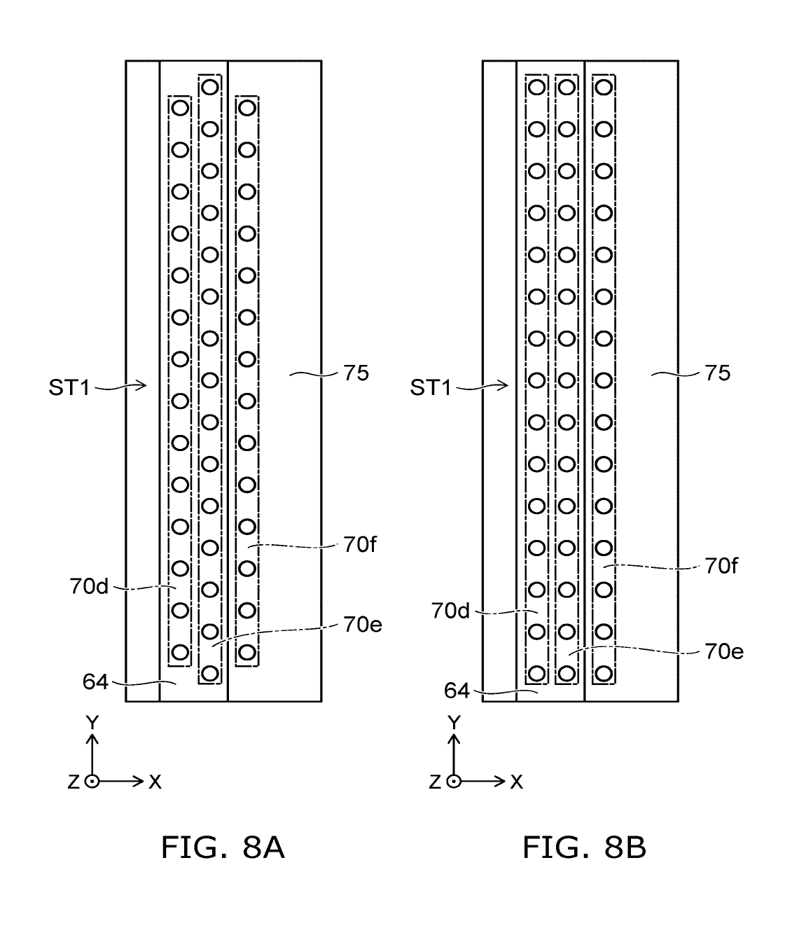

FIGS. 8A and 8B are magnified plan views of another portion of the semiconductor memory device 100 pertaining to the first embodiment.

As illustrated in FIG. 7A, a subset of the through portions 70 configure a first row 70a, a second row 70b, and a third row 70c disposed in the X-direction.

At least one portion of at least one of the through portions 70 in the first row 70a is not aligned with at least one portion of at least one of the through portions 70 in the second row 70b, in terms of the Y-direction. In addition, at least one portion of at least one of the through portions 70 in the third row 70c is not aligned with at least one portion of at least one of the through portions 70 in the second row 70b, in terms of the Y-direction.

In the example illustrated in FIG. 7A, a portion of at least one of the through portions 70 in the first row 70a may be aligned with a portion of at least one of the through portions 70 in the second row 70b, in terms of the Y-direction. In addition, a portion of at least one of the through portions 70 in the third row 70c may be aligned with a portion of at least one of the through portions 70 in the second row 70b, in terms of the Y-direction.

As an alternative, as illustrated in FIG. 7B, at least one portion of at least one of the through portions 70 in the first row 70a may be aligned with at least one portion of at least one of the through portions 70 in the second row 70b, in terms of the Y-direction. At least one portion of at least one of the through portions 70 in the third row 70c may be aligned with at least one portion of at least one of the through portions 70 in the second row 70b, in terms of the Y-direction.

As illustrated in FIG. 8A, a subset of the through portions 70 configure a fourth row 70d, a fifth row 70e, and a sixth row 70f disposed in the Y-direction.

At least one portion of at least one of the through portions 70 in the fourth row 70d is not aligned with at least one portion of at least one of the through portions 70 in the fifth row 70e, in terms of the X-direction. In addition, at least one portion of at least one of the through portions 70 in the sixth row 70f is not aligned with at least one portion of at least one of the through portions 70 in the fifth row 70e, in terms of the X-direction.

In the example illustrated in FIG. 8A, a portion of at least one of the through portions 70 in the fourth row 70d may be aligned with a portion of at least one of the through portions 70 in the fifth row 70e, in terms of the X-direction. In addition, a portion of at least one of the through portions 70 in the sixth row 70f may be aligned with a portion of at least one of the through portions 70 in the fifth row 70e, in terms of the X-direction.

As an alternative, as illustrated in FIG. 8B, at least one portion of at least one of the through portions 70 in the fourth row 70d may be aligned with at least one portion of at least one of the through portions 70 in the fifth row 70e, in terms of the X-direction. In addition, at least one portion of at least one of the through portions 70 in the sixth row 70f may be aligned with at least one portion of at least one of the through portions 70 in the fifth row 70e, in terms of the X-direction.

Any shape may be used for the through portions 70 in terms of cross-section orthogonal to the Z-direction. As one example, the shape of the through portions 70 in such a cross-section may be circular or may be elliptical.

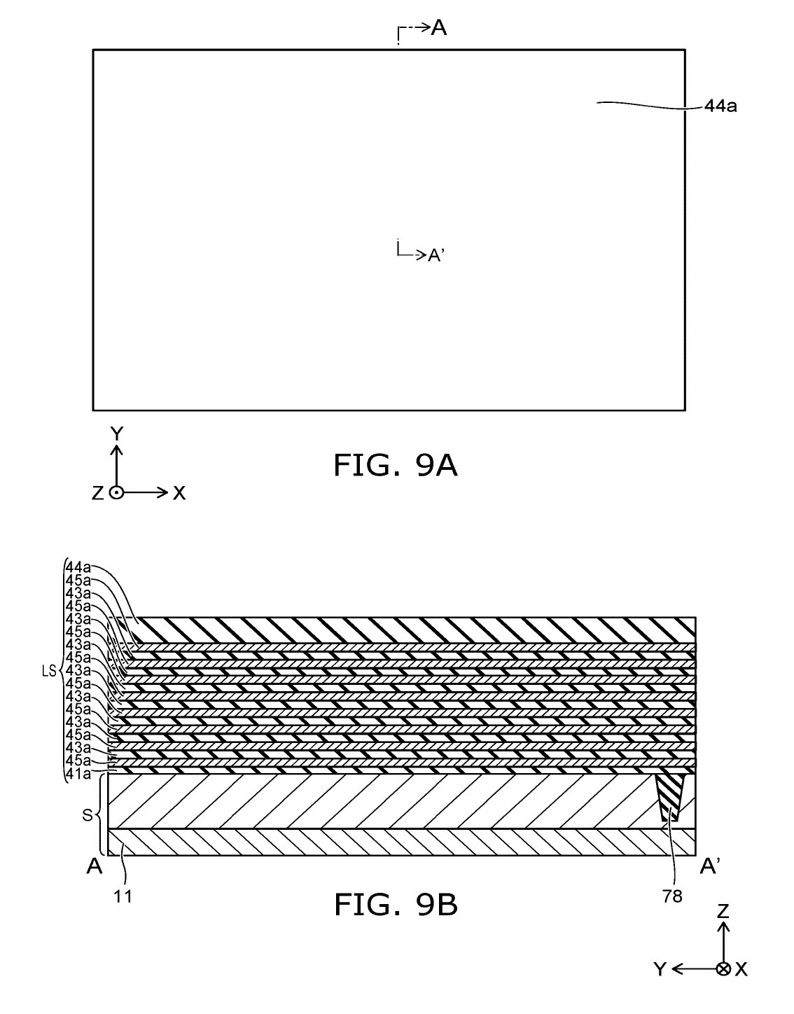

FIGS. 9A and 9B to 16A and 16B are process diagrams illustrating a manufacturing process for the semiconductor memory device 100 pertaining to the first embodiment.

FIGS. 9A, 10A, 11A, and 13A are plan view diagrams of mid-process states.

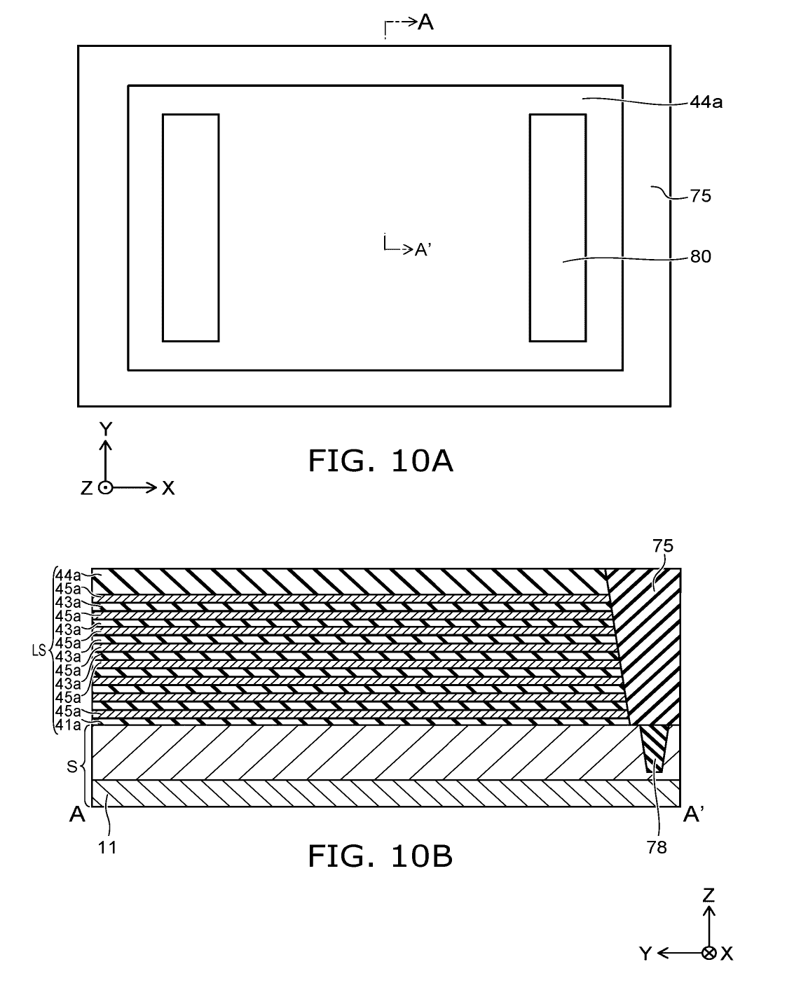

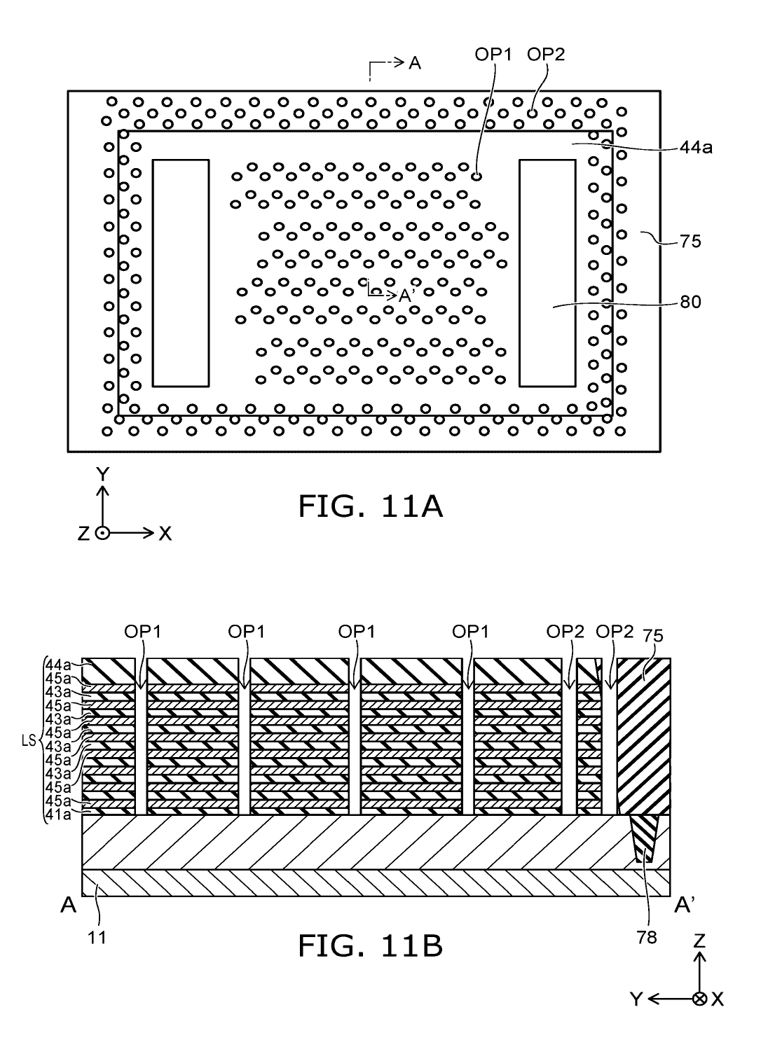

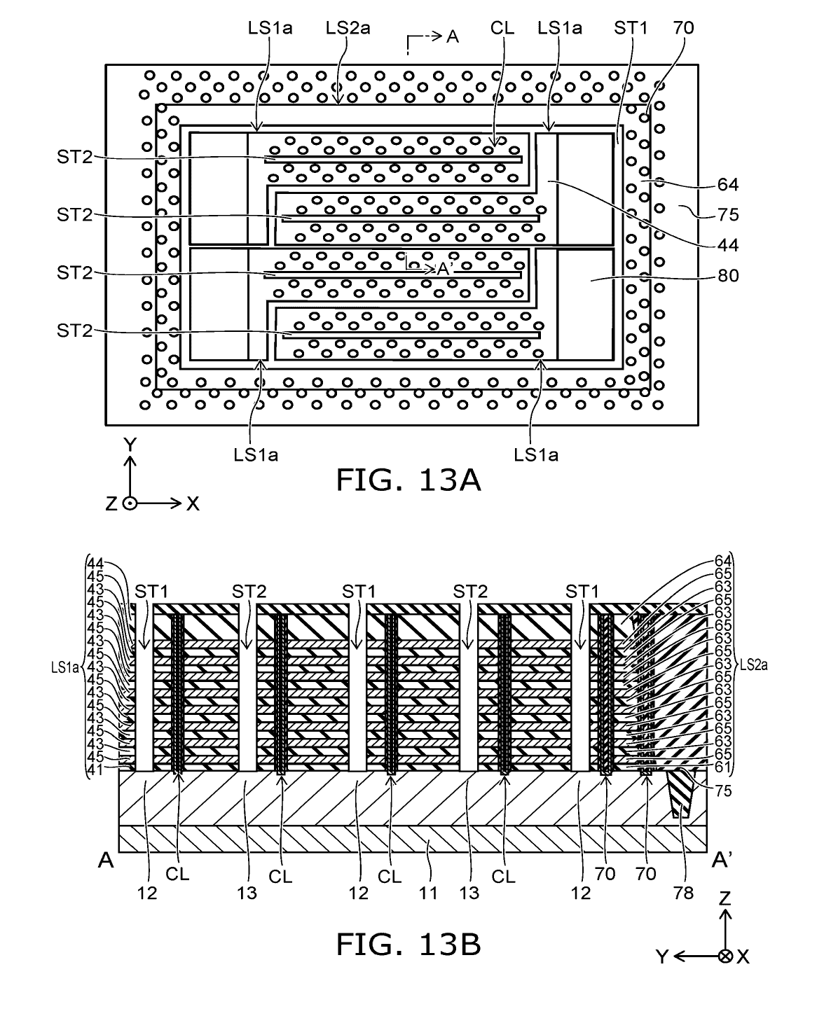

FIG. 9B is a cross-sectional diagram of A-A′ in FIG. 9A. FIG. 10B is a cross-sectional diagram of A-A′ in FIG. 10A. FIG. 11B is a cross-sectional diagram of A-A′ in FIG. 11A. FIG. 13B is a cross-sectional diagram of A-A′ in FIG. 13A.

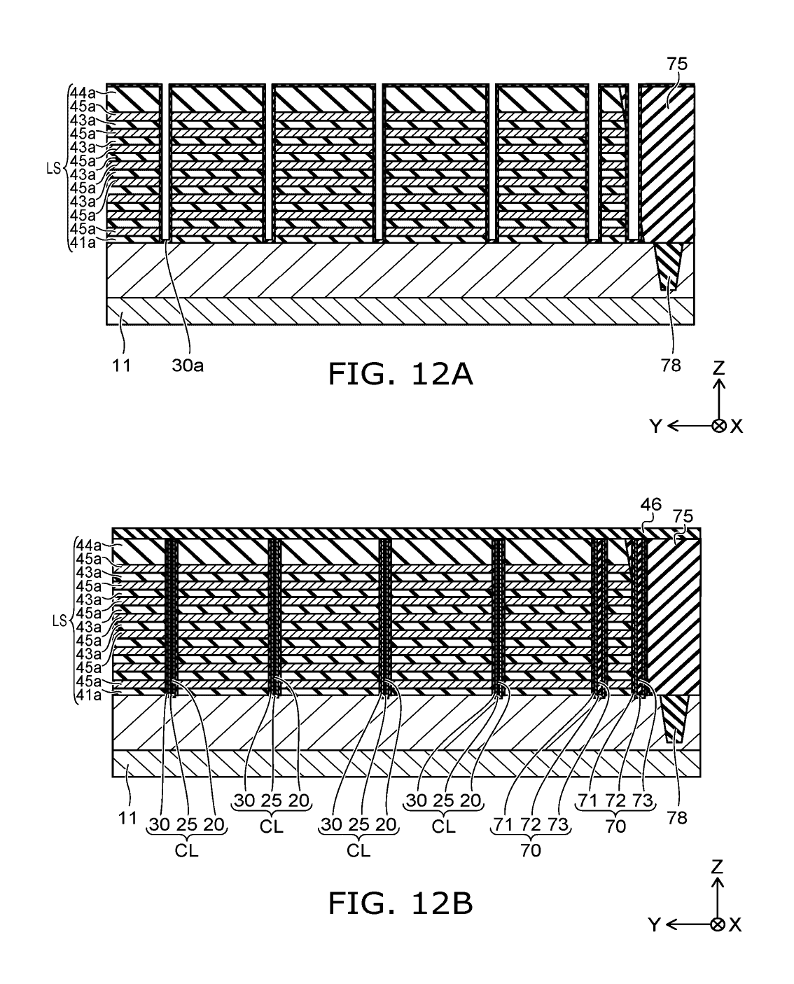

FIGS. 12A, 12B, 14A, 14B, 15A, and 15B are cross-sectional diagrams of positions corresponding to the respective A-A′ cross-sections of FIGS. 9A, 10A, 11A, and 13A.

The semiconductor layer S is omitted from FIG. 9A and subsequent drawings. The insulating layer 46 is omitted from FIGS. 11A and 13A.

A semiconductor substrate is prepared. The main component of the semiconductor substrate is silicon, for example. At least one portion of the semiconductor substrate corresponds to at least one portion of the semiconductor layer S illustrated in FIGS. 2 and 3. Ion injection of n-type impurities is performed on the surface of the semiconductor layer S, forming the n-type semiconductor region 11. Phosphorus and arsenic may be used as the n-type impurities, for example. The insulating portion 78 is formed on the semiconductor layer S, surrounding a portion of the n-type semiconductor region 11.

The insulating layer 41a is formed on the semiconductor layer S having the n-type semiconductor region 11 and the insulating portion 78 formed thereon. A plurality of sacrificial layers 45a, a plurality of insulating layers 43a, and an insulating layer 44a are formed on the insulating layer 41a. FIGS. 9A and 9B illustrate this point in the process. The number of the sacrificial layers 45a and the number of the insulating layers 43a are adjustable. No limitation is intended to the example of the number of these layers illustrated in FIG. 9B.

The insulating layers 41a, 43a, and 44a are, for example, silicon oxide layers. The sacrificial layers 45a are, for example, silicon nitride layers. These layers are formed using a chemical vapor deposition (hereinafter, CVD) method, for example.

A portion of a stacked body LS including the insulating layer 41a, the sacrificial layers 45a, the insulating layers 43a, and the insulating layer 44a is removed using a reactive ion etching (hereinafter, RIE) method, for example. Through this process, a side wall of the stacked body LS is exposed, and a portion of a top face of each of the sacrificial layers 45a is also exposed. Forming an insulating body in the portion where the stacked body LS has been removed serves to provide the insulating body at a periphery of the stacked body LS, and to cover the exposed top faces of the sacrificial layers 45a with the insulating body. The insulating portion 75 and the insulating portion 80 are formed and planarized by polishing the top face of the insulating body. FIGS. 10A and 10B illustrate this point in the process.

A plurality of openings OP1 and a plurality of openings OP2 are formed so as to pass through the stacked body LS. The position at which each of the openings OP1 is formed corresponds to one of the positions at which the columns CL are formed. The position at which each of the openings OP2 is formed corresponds to one of the positions at which the through portions 70 are formed. FIGS. 11A and 11B illustrate this point in the process.

A memory layer 30a, which includes a charge storage layer and a tunnel layer, is formed on an inner wall of each of the opening OP1 and on the insulating layer 44a, as illustrated in FIG. 12A.

A semiconductor layer 20a is formed on the memory layer 30a, and an insulating layer 25a is formed on the semiconductor layer 20a. A portion of the memory layer 30a formed at a bottom portion of each of the openings OP1 may be removed prior to forming the semiconductor layer 20a.

Any excess material deposited on the top of the insulating layer 44a may be removed using a chemical mechanical polishing (hereinafter, CMP) method, for example. The columns CL are formed with mutual separation through this process. The insulating layers 46 are formed on the insulating layers 44a, as illustrated in FIG. 12B. The insulating layers 46 are silicon oxide layers, for example, formed using the CVD method.

As illustrated in FIGS. 13A and 13B, the slits ST1 and the slits ST2 are formed so as to pass through the stacked body LS. The slits ST1 and ST2 are formed using the RIE method, for example. Through this process, the stacked body LS is divided, thus forming a first stacked body LS1a and a second stacked body LS2a. Meanwhile, as illustrated in FIGS. 2 and 3, the insulating layers 41, 43, 44, 61, 63, and 64 are formed through this process.

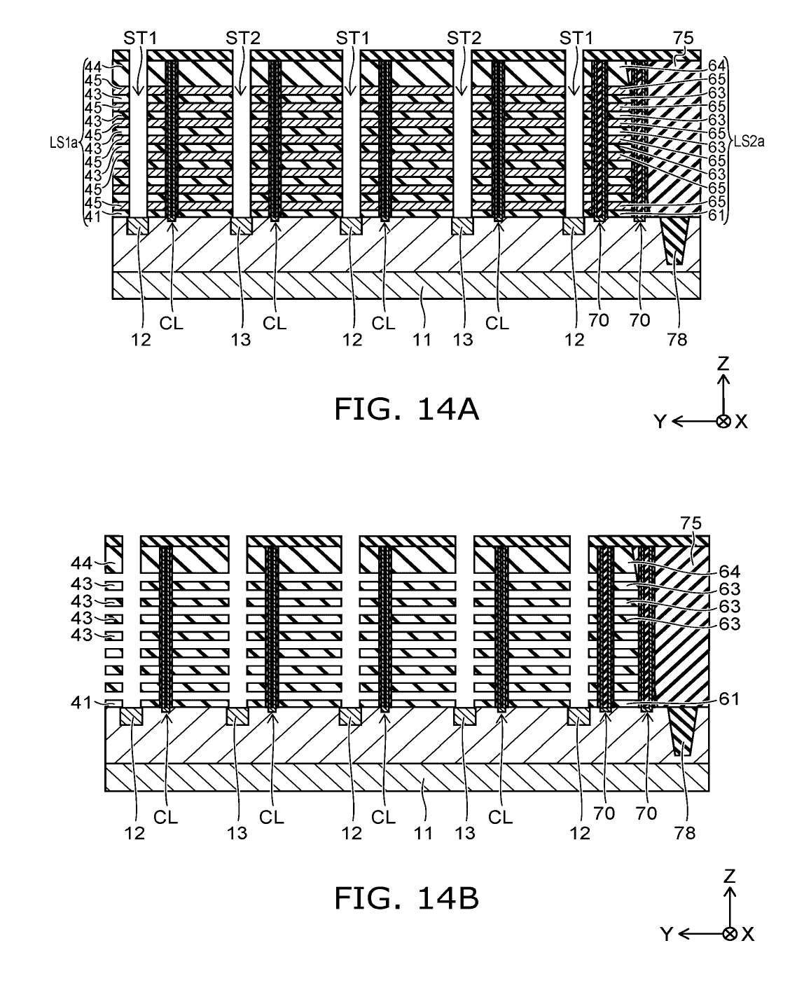

Ion injection of n-type impurities is performed through the slits ST1. Ion injection of p-type impurities is performed through the slits ST2. The semiconductor layer S is heated, thereby activating the impurities. Thus, as illustrated in FIG. 14A, the n-type semiconductor regions 12 and the p-type semiconductor regions 13 are formed.

The sacrificial layers 45 are removed through the slits ST1 and ST2, using wet etching. An alkaline chemical solution such as a potassium hydroxide (KOH) solution, for example, may be used as an etching liquid. FIG. 14B illustrates this point in the process.

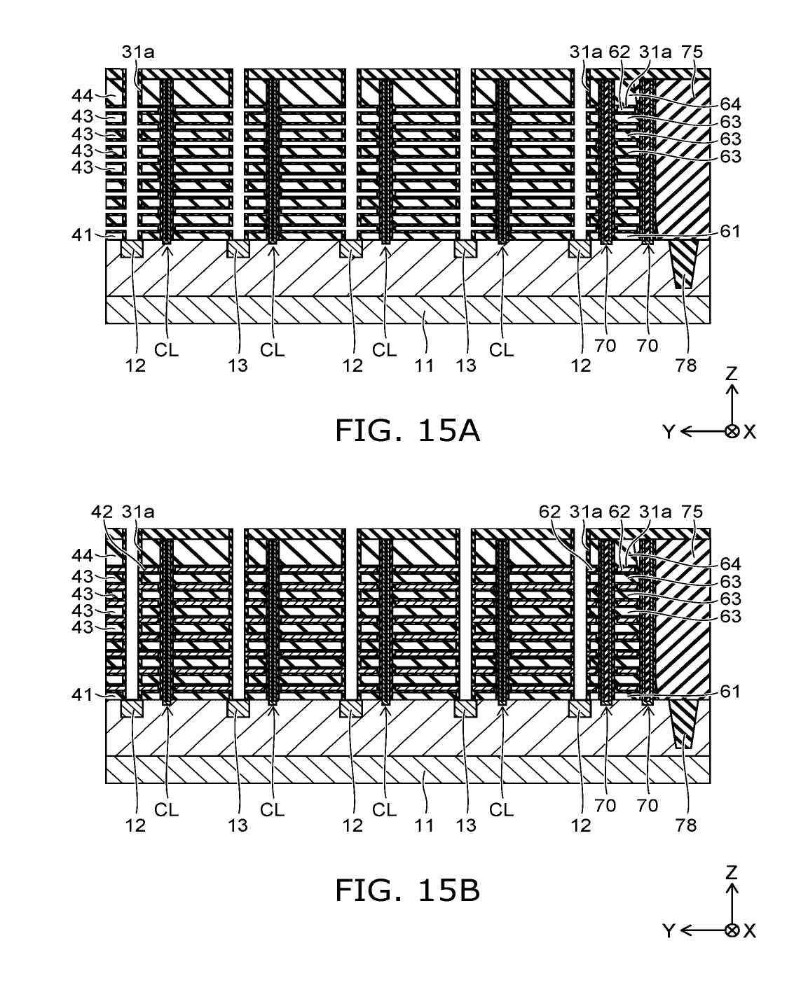

An insulating layer 31a is formed on the side walls of the columns CL and on each of the insulating layers, using an atomic layer deposition (hereinafter, ALD) method, for example. The insulating layer 31a is a silicon oxide layer, for example. FIG. 15A illustrates this point in the process.

A conductive layer is formed on the insulating layer 31a using the CVD method, for example. This conductive layer is, for example, a tungsten layer. Portions of this conductive layer formed inside the slits ST1 and the slits ST2 are removed. FIG. 15B illustrates this point in the process. The conductive layers 42 and 62 are formed by this process. The first stacked body LS1 including the insulating layer 41, the conductive layers 42, the insulating layers 43, and the insulating layer 44, as well as the second stacked body LS2 including the insulating layer 61, the conductive layers 62, the insulating layers 63, and the insulating layer 64 are formed at the same time.

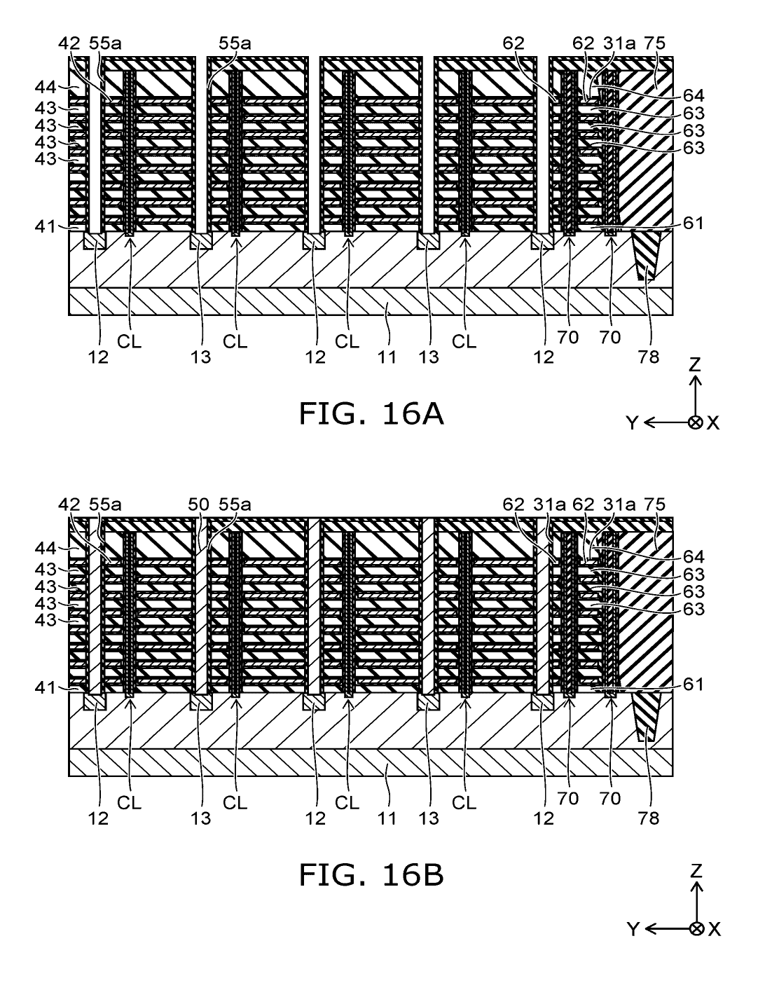

An insulating layer 55a is formed on the inner walls of the slits ST1, on the inner walls of the slits ST2, and on the insulating layer 46 using the ALD method, for example. The insulating layer 55a is a silicon oxide layer, for example. As illustrated in FIG. 16A, portions of the insulating layer 55a where a bottom portion of each of the slits ST1 and a bottom portion of each of the slits ST2 are formed are removed using the RIE method, for example.

A conductive layer is formed on the bottom portions of each of the slits ST1, on the bottom portions of each of the slits ST2, and on the insulating layer 55a. A portion of this conductive layer formed on the insulating layer 46 is removed using the CMP method, for example, as illustrated in FIG. 16B.

A plurality of holes are formed in the insulating portion 80. The holes are formed so as to expose a portion of the top face of each of the conductive layers 42 through the respective holes. The contacts 81 are formed by, for example, filling the holes with a metal material such as tungsten.

The semiconductor memory device 100 is obtained through the above process.

According to this embodiment, the through portions 70 are provided in the second stacked body LS2. As such, this enables a reduction in the possibility of the insulating layers within the second stacked body LS2 collapsing while the semiconductor memory device 100 is being manufactured.

Specifically, after forming the slits ST1 and ST2 as illustrated in FIG. 14A, the sacrificial layers 45 are removed as illustrated in FIG. 14B. Here, the insulating layers 43 and 44 are supported by the columns CL that extend in these insulating layers.

Conversely, in a situation where the through portions 70 are not provided, the insulating layers 63 and 64 are, for example, supported by the insulating portion 75 that is in contact with side walls of each insulating layer. In such a situation, the insulating layers 63 and 64 are insufficiently supported in comparison to the situation where the insulating layers 63 and 64 are supported by the through portions 70. There is a risk that the insulating layers 63 and 64 may collapse upon removal of the sacrificial layers 45.

In particular, this problem tends to be pronounced in a situation where a face of the second stacked body LS2a that is in contact with the insulating portion 75 is tapered, and the number of stacked layers in the stacked body LS (as illustrated in FIG. 9B, for example) is increased. Having the face of the second stacked body LS2a that is in contact with the insulating portion 75 be tapered causes the length, in one of the X-direction and the Y-direction, of one of the insulating layers 63 at a position near the semiconductor layer S to be longer than the length, in one of the X-direction and the Y-direction, of one of the insulating layers 63 at a position far from the semiconductor layer S. As such, there is an increase in the volume of the insulating layers 63 supported at the contact surface between the insulating layers 63 and the insulating portion 75, thus further increasing the possibility of collapse.

As a result, this embodiment is particularly effective in a situation where the face of the second stacked body LS2a that is in contact with the insulating portion 75 is tapered.

Furthermore, providing the through portion 70 in plurality enables a further reduction in the possibility of collapse for the insulating layers 63 and 64 upon removal of the sacrificial layers 45. At this point, suitable division of the load on the insulating layers 63 and 64 among the through portions 70 is made possible by providing the through portions so as to surround each of the first stacked bodies LS1.

In a situation where the through portions 70 are arranged as illustrated in FIGS. 7A and 8A, the progression of the etching liquid between the insulating layers 63 of the second stacked body LS2a may be prevented in the removal of the sacrificial layers 45 in the process illustrated in FIG. 14B. As a result, in some situations, portions of the sacrificial layers 45 remain between the insulating layers 63 as the layers 69 illustrated in FIG. 6. Having the layers 69 remain between the insulating layers 63 enables a further reduction in the possibility of collapse for the insulating layers 63 and 64.

### Second Embodiment

A semiconductor memory device 200 is, for example, a nonvolatile semiconductor memory device, similarly to the semiconductor memory device 100.

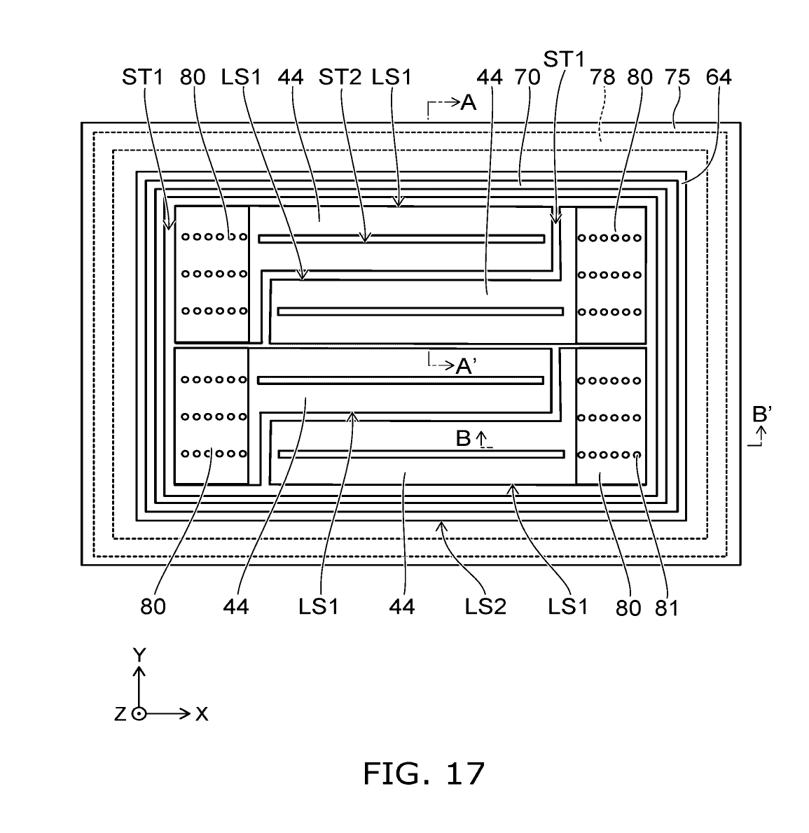

FIG. 17 is a plan view diagram illustrating a portion of the semiconductor memory device 200 pertaining to the second embodiment.

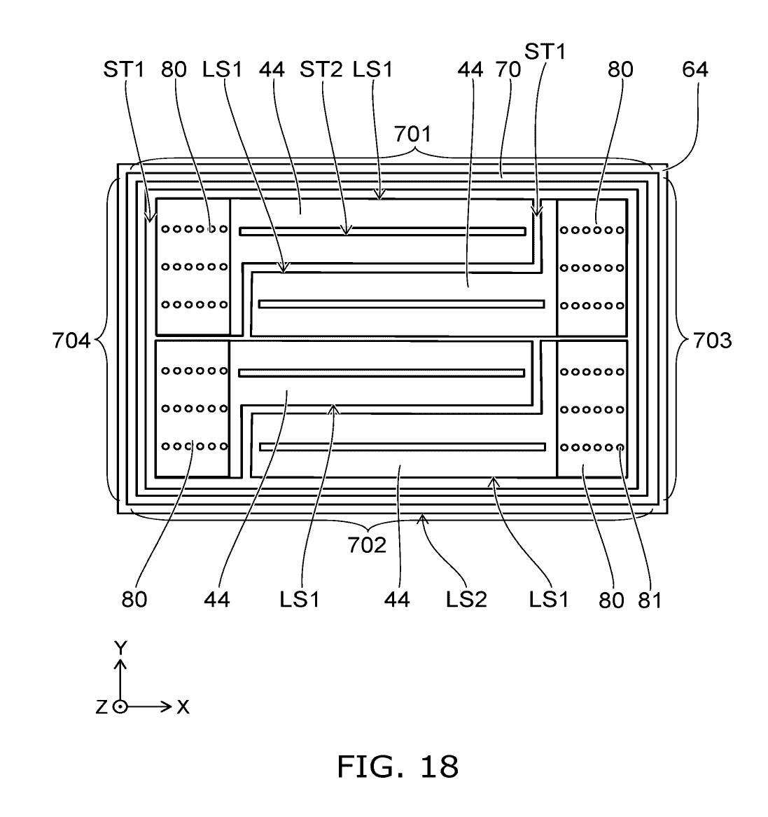

FIG. 18 is a magnified plan view diagram of a portion of the semiconductor memory device 200 pertaining to the second embodiment.

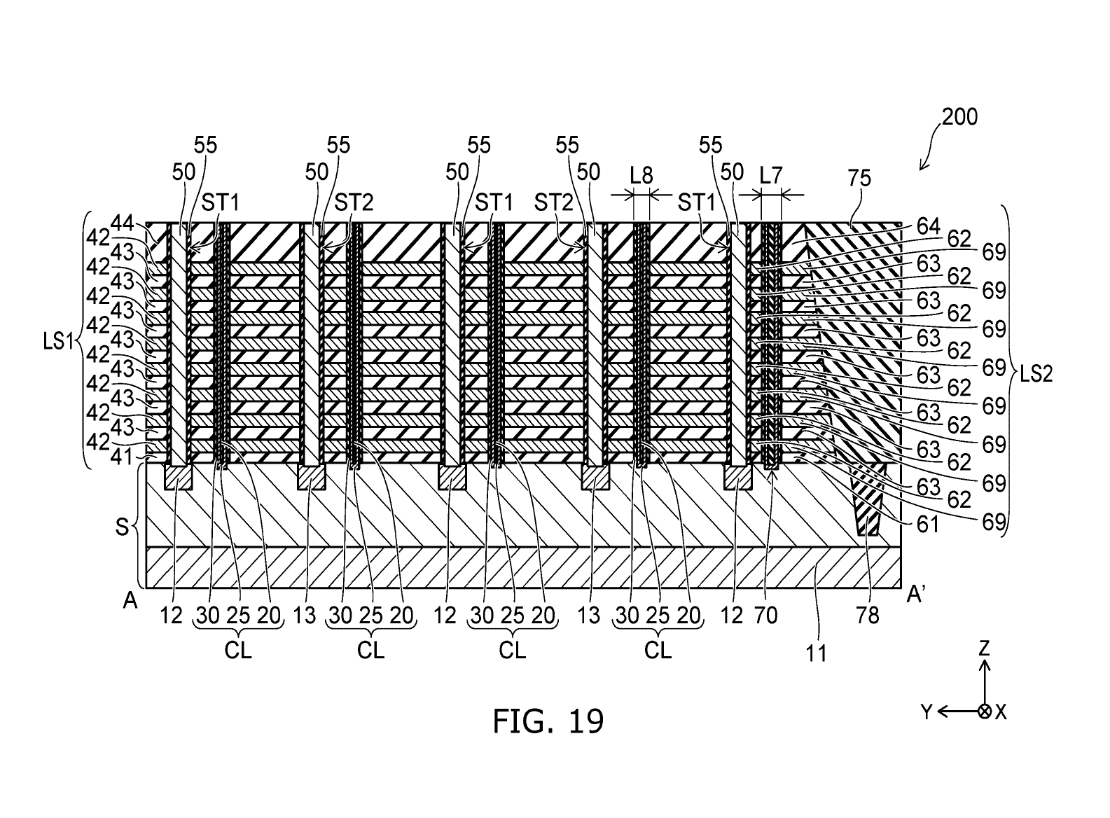

FIG. 19 is a cross-sectional diagram of A-A′ in FIG. 17.

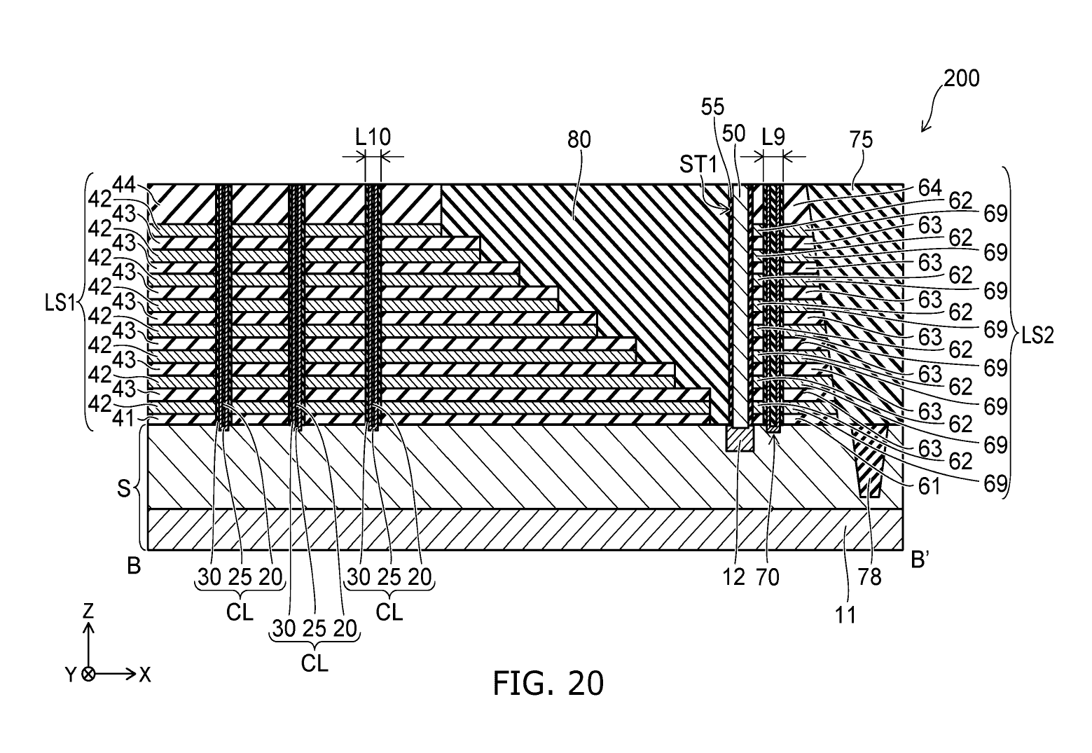

FIG. 20 is a cross-sectional diagram of B-B′ in FIG. 17.

In FIGS. 17 and 18, the detailed structure of the slits ST1 and of the slits ST2, as well as of the columns CL formed in the first stacked bodies LS1, are omitted for ease of understanding. In addition, FIG. 17 indicates a position at which the insulating portion 78 is provided in dashed lines, as seen in a plan view.

In comparison to the semiconductor memory device 100, the semiconductor memory device 200 differs in terms of the structure of the through portions 70, for example. The semiconductor memory device 200 may employ an identical configuration to the semiconductor memory device 100, with the exception of the configuration of the through portions 70.

As illustrated in FIG. 18, the through portions 70 each include a first portion 701 and a second portion 702 extending in the X-direction, and a third portion 703 and a fourth portion 704 extending in the Y-direction. That is, the length of the first portion 701 in the X-direction and the length of the second portion 702 in the X-direction are shorter than the length of the first portion 701 in the Y-direction and the length of the second portion 702 in the Y-direction. Also, the length of the third portion 703 in the Y-direction and the length of the fourth portion 704 in the Y-direction are shorter than the length of the third portion 703 in the X-direction and the length of the fourth portion 704 in the X-direction.

The first stacked bodies LS1 are provided between the first portion 701 and the second portion 702, in terms of the Y-direction. The first stacked bodies LS1 are provided between the third portion 703 and the fourth portion 704, in terms of the X-direction. The through portions 70 may be provided at the periphery of each of the first stacked bodies LS1.

The first portion 701 to the fourth portion 704 may be provided with mutual separation. In other words, the semiconductor memory device 200 may be surrounded by a plurality of through portions 701 to 704 having mutual separation. In such a situation, the through portions 701 and 702 extend in the X-direction, and the through portions 703 and 704 extend in the Y-direction. The first stacked bodies LS1 are provided between the through portions 701 and 702 in terms of the Y-direction, and provided between the through portions 703 and 704 in terms of the X-direction.

In the semiconductor memory device 200, the second stacked body LS2 includes the insulating layer 61, the conductive layers 62, the insulating layers 63, the insulating layer 64, and the layers 69, as illustrated in FIGS. 19 and 20.

The through portions 70 extend in the second stacked body only, for example. However, a subset of the through portions 70 may extend in the insulating portion 75, and another subset of the through portions 70 may extend in a portion of the second stacked body LS2.

The conductive layers 62 are provided between the through portions 70 and the conductive portion 50 (the slits ST1). The layers 69 are provided between pairs of the insulating layers 63 and between the through portions 70 and the insulating portion 75.

The width of each of the through portions 70 is, for example, greater than the diameter of the columns CL. That is, a length L7 in the Y-direction of the first portion 701 and a length in the Y-direction of the third portion 703 are longer than a length L8 in the Y-direction of the columns CL. In addition, a length L9 in the X-direction of the second portion 702 and a length in the X-direction of the fourth portion 704 are longer than a length L10 in the X-direction of the columns CL.

The semiconductor memory device 200 may include the through portion 70 in plurality. That is, the configuration may include one of the through portions 70 being surrounded by another one of the through portions 70.

According to this embodiment, the through portions 70 have portions extending in the X-direction and portions extending in the Y-direction. As such, the etching liquid is unlikely to reach outside the through portions 70 (the insulating portion 75 side) at the removal of the sacrificial layer 45. Accordingly, given that the layers 45 remain as the layers 69, this configuration enables a further reduction in the possibility of collapse for the insulating layers 63 and 64.

### Third Embodiment

A semiconductor memory device 300 is, for example, a nonvolatile semiconductor memory device, similarly to the semiconductor memory device 100.

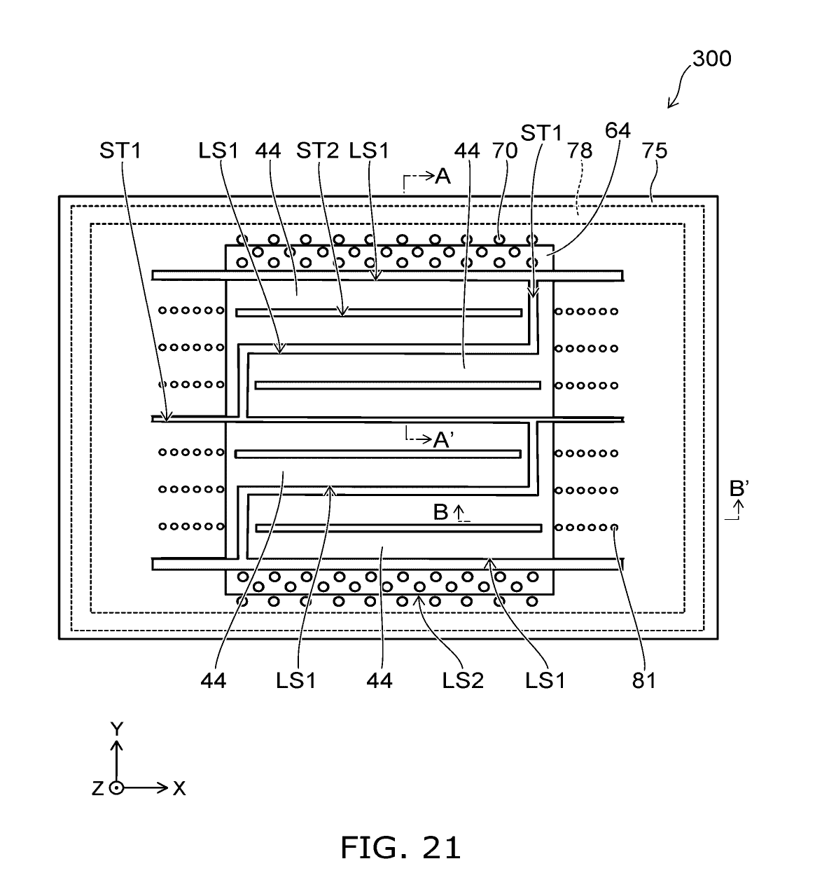

FIG. 21 is a plan view diagram illustrating a portion of the semiconductor memory device 300 pertaining to the third embodiment.

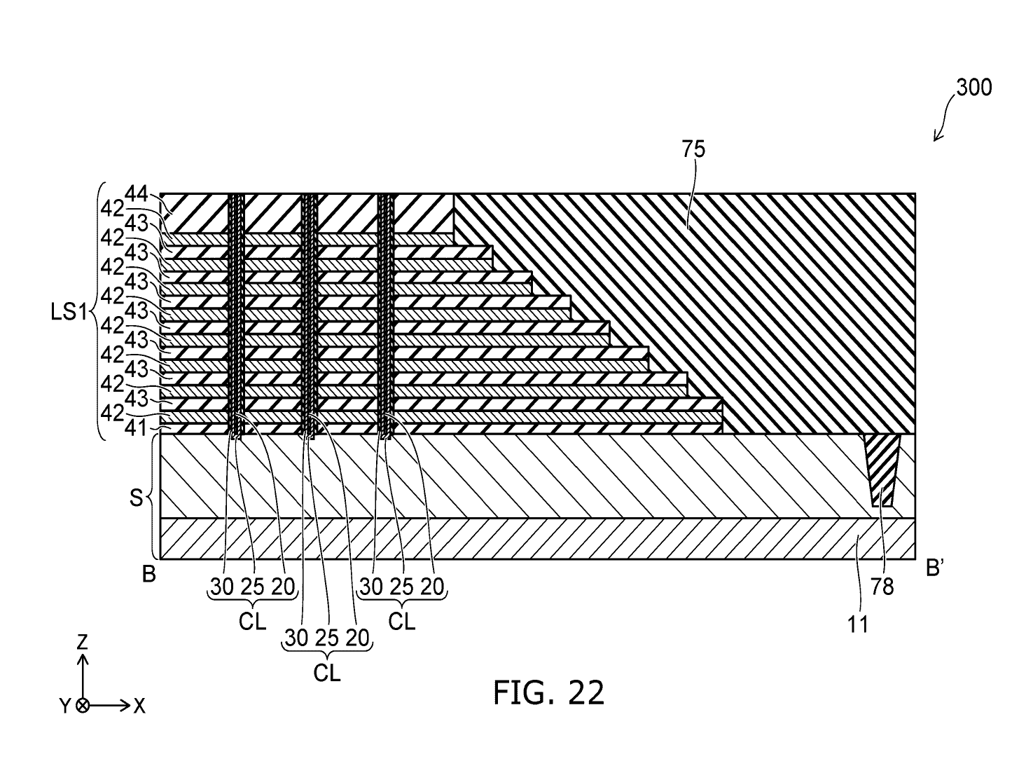

FIG. 22 is a cross-sectional diagram of B-B′ in FIG. 21.

In FIG. 21, the detailed structure of the slits ST1 and of the slits ST2, as well as of the columns CL formed in each of the first stacked portion LS1, are omitted for ease of understanding. In addition, FIG. 21 indicates a position at which the insulating portion 78 is provided in dashed lines, as seen in a plan view.

In comparison to the semiconductor memory device 100, the semiconductor memory device 300 differs in terms of the structure of the second stacked body LS2 and the structure of the insulating portion 78, for example. The semiconductor memory device 300 may employ an identical configuration to the semiconductor memory device 100, with the exception of the configurations of the second stacked body LS2 and the insulating portion 78.

As illustrated in FIG. 21, the first stacked bodies are aligned in the X-direction and the Y-direction. The second stacked body LS2 is provided in plurality at the periphery of the first stacked bodies LS1. Specifically, the second stacked bodies LS2 are provided such that the first stacked bodies LS1 are positioned between pairs of the second stacked bodies LS2 in terms of the Y-direction.

Slits ST are provided between the first stacked bodies LS1. The first stacked bodies LS1 are separated from each other by the slits ST1. The first stacked bodies LS1 are provided between the slits ST1, in terms of the Y-direction. As illustrated in FIG. 1, the slits ST2 are provided at positions surrounded by the first stacked bodies LS1, as seen from the Z-direction.

The first stacked bodies LS1 and the second stacked body LS2 are surrounded by the insulating portion 75. The through portions 70 are provided in a portion of the periphery of the first stacked bodies LS1. Specifically, the through portions 70 are provided such that the first stacked bodies LS1 and the second stacked bodies LS2 are positioned between the through portions 70 in terms of the Y-direction.

A subset of the first stacked bodies LS1 are covered by the insulating portion 75. A portion of the insulating portion 75 is provided between the slits ST1. As seen in a plan view, the insulating portion 78 is provided at the periphery of the first stacked bodies LS1 and the second stacked bodies LS2. The insulating portion 78 may overlap with the second stacked bodies LS2 as seen in a plan view.

The structure of the semiconductor memory device 300, as seen in a cross-sectional view along A-A′, may employ an identical configuration to that illustrated in a cross-sectional view along A-A′ of the semiconductor memory device 100. That is, the cross-sectional view along A-A′ of the semiconductor memory device 300 may be identical to the cross-sectional view along A-A′ of the semiconductor memory device 100 illustrated in FIG. 2.

As illustrated in FIG. 22, unlike the semiconductor memory device 100, the second stacked bodies LS2 are not provided in regions neighboring the first stacked bodies LS1 in the X-direction.

According to this embodiment, given that the second stacked bodies LS2 are not provided in the regions neighboring the first stacked bodies LS1 in the X-direction, this configuration enables a further reduction in the possibility of collapse for the second stacked bodies LS2 in the manufacture of the semiconductor memory device 300.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device, comprising:
a first stacked body including a plurality of first conductive layers and a plurality of first insulating layers, the first conductive layers and the first insulating layers being stacked in alternation;
a column extending in the first stacked body in a stacking direction of the first conductive layers and the first insulating layers, and including:
a semiconductor pillar extending in the stacking direction; and
a charge storage layer provided between the semiconductor pillar and the first stacked body;
a second stacked body being separated from the first stacked body, the second stacked body being provided on at least one portion of a periphery of the first stacked body, and the second stacked body including a plurality of second conductive layers and a plurality of second insulating layers, the second conductive layers and the second insulating layers being stacked in alternation;
a through portion extending in at least one portion of the second stacked body in the stacking direction; and
a first insulating portion provided at the periphery of the first stacked body and at a periphery of the second stacked body.

2. The semiconductor memory device according to claim 1, wherein
the first stacked body is provided in plurality,
the plurality of first stacked bodies are separated from each other, and
the second stacked body is provided on at least a portion of a periphery of the plurality of first stacked bodies.

3. The semiconductor memory device according to claim 2, wherein
a portion of the through portion extends in a portion of the first stacked bodies, and
another portion of the through portion extends in the second stacked body.

4. The semiconductor memory device according to claim 2, wherein
the plurality of first stacked bodies are surrounded by the second stacked body.

5. The semiconductor memory device according to claim 4, wherein
the through portion is provided in plurality,
the plurality of through portions are separated from each other, and
the plurality of through portions are provided on a periphery of the plurality of first stacked bodies.

6. The semiconductor memory device according to claim 5, wherein
the plurality of first stacked bodies are arranged in a first direction orthogonal to the stacking direction.

7. The semiconductor memory device according to claim 5, wherein
the plurality of first stacked bodies are arranged in a first direction and a second direction,
the first direction is orthogonal to the stacking direction, and
the second direction is orthogonal to the stacking direction and to the first direction.

8. The semiconductor memory device according to claim 5, wherein
a subset of the through portions are arranged in a first direction orthogonal to the stacking direction, and
another subset of the through portions are arranged in a second direction orthogonal to the stacking direction and to the first direction.

9. The semiconductor memory device according to claim 5, wherein
a subset of the through portions configure a first row arranged along a first direction,
another subset of the through portions configure a second row arranged along the first direction,
at least a portion of at least one of the through portions in the first row is not aligned with at least a portion of at least one of the through portions in the second row in terms of a second direction,
the first direction is orthogonal to the stacking direction, and
the second direction is orthogonal to the stacking direction and to the first direction.

10. The semiconductor memory device according to claim 5, wherein
a subset of the through portions configure a first row arranged along a first direction,
another subset of the through portions configure a second row arranged along the first direction,
at least a portion of at least one of the through portions in the first row is aligned with at least a portion of at least one of the through portions in the second row in terms of a second direction,
the first direction is orthogonal to the stacking direction, and
the second direction is orthogonal to the stacking direction and to the first direction.

11. The semiconductor memory device according to claim 5, wherein
at least one of the through portions has a shape that is elliptical in a first cross-section, and
the first cross-section is orthogonal to the stacking direction.

12. The semiconductor memory device according to claim 4, wherein
the through portion includes a first portion and a second portion extending along a first direction orthogonal to the stacking direction, and
the first stacked bodies are provided between the first portion and the second portion in terms of a second direction orthogonal to the stacking direction and to the first direction.

13. The semiconductor memory device according to claim 4, wherein
the through portion is provided in plurality,
the plurality of through portions extend in a first direction orthogonal to the stacking direction, and
the plurality of first stacked bodies are provided between a subset of the plurality of through portions and another subset of the plurality of through portions, in terms of a second direction orthogonal to the stacking direction and to the first direction.

14. The semiconductor memory device according to claim 1, wherein
a length of the through portion in a first direction orthogonal to the stacking direction is longer than a length of the column in the first direction.

15. The semiconductor memory device according to claim 1, wherein
the through portion includes a first semiconductor portion extending in the stacking direction, and
the first semiconductor portion includes a material identical to a material in the semiconductor pillar.

16. The semiconductor memory device according to claim 15, wherein
a distance from an end in a first direction to another end in the first direction of the first stacked body is longer than a distance from an end in the first direction to another end in the first direction of the semiconductor pillar, and
the first direction is a direction orthogonal to the stacking direction.

17. The semiconductor memory device according to claim 1, wherein
the second conductive layers are electrically separated from the first conductive layers.

18. The semiconductor memory device according to claim 1, further comprising:
a first semiconductor layer, the first stacked body, the second stacked body, and the through portion being provided on the first semiconductor layer; and
a second insulating portion provided within the first semiconductor layer,
wherein
as viewed from the stacking direction, the second insulating portion surrounds at least a portion of the first stacked body and the second stacked body, and surrounds the through portion.

19. The semiconductor memory device according to claim 1, wherein
the second stacked body is in contact with the first insulating portion, and
a contact surface of the second stacked body and the first insulating portion is slanted with respect to the stacking direction.

20. The semiconductor memory device according to claim 1, wherein
the second stacked body further includes a second semiconductor layer, and
the second semiconductor layer is provided between at least one of the second conductive layers and the first insulating portion.
